(19) United States
(12) Patent Application Publication
(10) Pub. No.: US 2026/0086612 A1
(43) Pub. Date: Mar. 26, 2026

(54) DYNAMIC CONTROL OF LIQUID-ASSISTED AIR COOLING SYSTEMS

(71) Applicant: Dell Products L.P., Round Rock, TX (US)

(72) Inventors: Vinoth Raja P, Thiruvarur (IN); Karthick Nagarajan, Bangalore (IN)

(21) Appl. No.: 18/894,358

(22) Filed: Sep. 24, 2024

(51) Int. Cl. G06F 1/20; H05K 7/20

(52) U.S. Cl. CPC G06F 1/20; H05K 7/20154

(57) ABSTRACT

An apparatus comprises a processing device configured to monitor status information for electronic equipment of an information technology asset, at least a portion of the electronic equipment being at least partially cooled by at least one pump of a liquid-assisted air cooling system. The at least one processing device is also configured to determine configuration information for at least one motor of the at least one pump of the liquid-assisted air cooling system based at least in part on the monitored status information. The at least one processing device is further configured to control operation of the at least one motor of the at least one pump of the liquid-assisted air cooling system based at least in part on the determined configuration information.

### BACKGROUND

A given set of electronic equipment configured to provide desired system functionality is often installed in a chassis or other housing. Such equipment can include, for example, various arrangements of storage devices, memory modules, processors, circuit boards, interface cards and power supplies used to implement at least a portion of a storage system, a server system or other type of information processing system. Various cooling mechanisms may be utilized for electronic equipment that is installed in a chassis or other housing, including air cooling mechanisms, direct liquid cooling (DLC) mechanisms, and liquid-assisted air cooling (LAAC) mechanisms.

### SUMMARY

Illustrative embodiments of the present disclosure provide techniques for dynamic control of liquid-assisted air cooling systems.

In one embodiment, an apparatus comprises at least one processing device comprising a processor coupled to a memory. The at least one processing device is configured to monitor status information for electronic equipment of an information technology asset, at least a portion of the electronic equipment being at least partially cooled by at least one pump of a liquid-assisted air cooling system. The at least one processing device is also configured to determine configuration information for at least one motor of the at least one pump of the liquid-assisted air cooling system based at least in part on the monitored status information. The at least one processing device is further configured to control operation of the at least one motor of the at least one pump of the liquid-assisted air cooling system based at least in part on the determined configuration information.

These and other illustrative embodiments include, without limitation, methods, apparatus, networks, systems and processor-readable storage media.

### BRIEF DESCRIPTION OF THE DRAWINGS

FIG. 1 is a block diagram of an information processing system configured for dynamic control of liquid-assisted air cooling systems in an illustrative embodiment.

FIG. 2 is a flow diagram of an exemplary process for dynamic control of liquid-assisted air cooling systems in an illustrative embodiment.

FIG. 3 shows a liquid-assisted air cooling system in an illustrative embodiment.

FIG. 4 shows pumps of a liquid-assisted air cooling system which are controlled by a baseboard management controller for cooling of server hardware resources in an illustrative embodiment.

FIGS. 5A and 5B show open and closed loop control modes for a liquid-assisted air cooling system in an illustrative embodiment.

FIG. 6 shows a system flow for a baseboard management controller to manage a liquid-assisted air cooling system in open and closed loop control modes in an illustrative embodiment.

FIGS. 7A and 7B show examples of liquid-assisted air cooling control without and management by a baseboard management controller in an illustrative embodiment.

FIGS. 8 and 9 show examples of processing platforms that may be utilized to implement at least a portion of an information processing system in illustrative embodiments.

### DETAILED DESCRIPTION

Illustrative embodiments will be described herein with reference to exemplary information processing systems and associated computers, servers, storage devices and other processing devices. It is to be appreciated, however, that embodiments are not restricted to use with the particular illustrative system and device configurations shown. Accordingly, the term “information processing system” as used herein is intended to be broadly construed, so as to encompass, for example, processing systems comprising cloud computing and storage systems, as well as other types of processing systems comprising various combinations of physical and virtual processing resources. An information processing system may therefore comprise, for example, at least one data center or other type of cloud-based system that includes one or more clouds hosting tenants that access cloud resources.

Information technology (IT) assets, also referred to herein as IT equipment, may include various compute, network and storage hardware or other electronic equipment, and are typically installed in an electronic equipment chassis. The electronic equipment chassis may form part of an equipment cabinet (e.g., a computer cabinet) or equipment rack (e.g., a computer or server rack, also referred to herein simply as a “rack”) that is installed in a data center, computer room or other facility. Equipment cabinets or racks provide or have physical electronic equipment chassis that can house multiple pieces of equipment, such as multiple computing devices (e.g., blade or compute servers, storage arrays or other types of storage servers, storage systems, network devices, etc.). An electronic equipment chassis typically complies with established standards of height, width and depth to facilitate mounting of electronic equipment in an equipment cabinet or other type of equipment rack. For example, standard chassis heights such as 1U, 2U, 3U, 4U and so on are commonly used, where U denotes a unit height of 1.75 inches (1.75″) in accordance with the well-known EIA-310-D industry standard. Cooling mechanisms for electronic equipment installed in an electronic equipment chassis or other housing include, but are not limited to, air cooling (e.g., using fans), direct liquid cooling (DLC), and liquid-assisted air cooling (LAAC).

LAAC may advantageously be set up at the system level without any external infrastructure dependency, and includes one or more LAAC pumps. In conventional approaches, LAAC pumps are driven at a constant predetermined speed, as LAAC systems do not have any direct thermal control and monitoring mechanism which can identify the ideal speed of the LAAC pumps and flow of liquid therethrough (e.g., based on the operating state of the electronic equipment that is being cooled by the LAAC system). Since LAAC pump motors are typically run at a constant high speed by default, this affects the component life and requires constant high values of power consumption even when the electronic equipment being cooled (e.g., high-end graphical processing units (GPUs) or other hardware accelerators) using the LAAC system is not being utilized or is being lightly utilized.

Further, if a LAAC pump fails during maximum utilization of the electronic equipment that is being cooled by the LAAC system, the electronic equipment may experience insufficient thermal cooling which can lead to system shutdown and/or unexpected thermal damage. The status of LAAC pumps and the flow of liquid through LAAC pumps is not directly monitored by the electronic equipment being cooled, or by a controller (e.g., a baseboard management controller (BMC)) of an IT asset in which the electronic equipment is installed. The BMC or other controller may have thermal monitoring and control functionality (e.g., for monitoring the temperature of the electronic equipment installed in an IT asset, and for controlling operation of one or more air cooling mechanisms such as fans configured for cooling of the electronic equipment installed in the IT asset). Instead, the LAAC pumps may be controlled by a LAAC module of a power distribution board (PDB) complex programmable logic device (CPLD). Further, a radiator of a LAAC system may, depending on the air cooling mechanisms utilized, cause high acoustic levels even when the electronic equipment being cooled is idle and one or more fans do not need to run at a high rotations per minute (RPM) setting.

Illustrative embodiments provide technical solutions for intelligent control of a LAAC system, where a BMC or other controller (of an IT asset having electronic equipment installed therein which is being cooled using a LAAC system) directly manages the operation of LAAC pumps and other components of the LAAC system. In some embodiments, this is achieved through utilization of one or more temperature sensors to regulate the flow of liquid through the LAAC pumps of the LAAC system. The technical solutions are thus able to ensure optimal or improved cooling of electronic equipment while maintaining a harmonious balance between temperature control and liquid flow management. The BMC or other controller, in some embodiments, is further able to detect LAAC pump failure or other failure of a LAAC system and to adjust operation of the electronic equipment being cooled to prevent system shutdown and mitigate the risk of thermal damage. As an example, where the electronic equipment being cooled is one or more GPUs, this may include the BMC or other controller triggering a cascaded GPU power break (PWRBRK) signal that limits the power consumption of GPUs via Open Compute Protocol (OCP) Accelerator Module (OCM)/Socket (SXM) power capping input/output (IO) pins of the GPUs.

In some embodiments, the technical solutions allow for a hybrid cooling approach that integrates both open loop and closed loop control methods for directly managing LAAC systems. The technical solutions are able to harmonize efficiency and precision in regulating liquid flow, ensuring optimal or improved cooling performance utilizing LAAC systems. The hybrid cooling for the LAAC system is advantageously under the full control of the BMC or other controller of an IT asset, ensuring seamless operation. Additionally, the integration of staggered GPU PWRBRK or other power consumption control features can address various failure scenarios (e.g., failure of LAAC pumps or other components of a LAAC system), enabling uninterrupted system functionality. The technical solutions further provide enhanced methods for regulating LAAC pumps of an LAAC system based on the thermal requirements of components or other electronic equipment that is being cooled by the LAAC system, further optimizing or improving cooling efficiency.

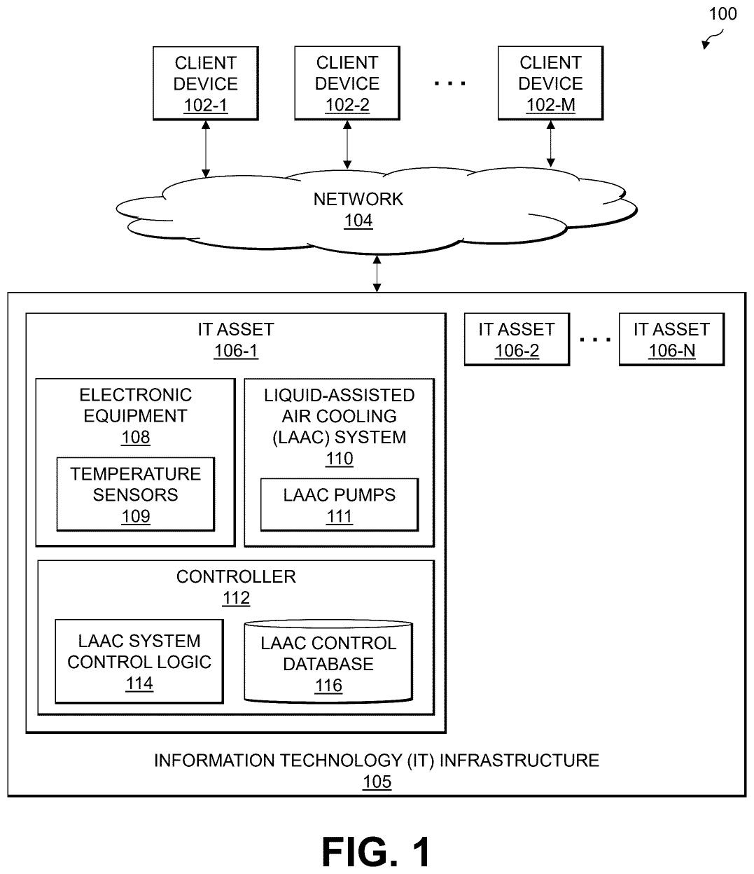

FIG. 1 shows an information processing system 100 configured in accordance with an illustrative embodiment. The information processing system 100 is assumed to be built on at least one processing platform and provides functionality for dynamic control of LAAC systems. The information processing system 100 includes a set of client devices 102-1, 102-2, . . . 102-M (collectively, client devices 102) which are coupled to a network 104. Also coupled to the network 104 is an IT infrastructure 105 comprising a set of IT assets 106-1, 106-2, . . . 106-N (collectively, IT assets 106). The IT assets of the IT infrastructure 105 may comprise physical and/or virtual computing resources. Physical computing resources may include physical hardware such as servers, storage systems, networking equipment, Internet of Things (IoT) devices, other types of processing and computing devices including desktops, laptops, tablets, smartphones, etc. Virtual computing resources may include virtual machines (VMs), containers, etc. which run on the physical computing resources.

As shown in FIG. 1, the IT assets 106-1 includes electronic equipment 108 which is associated with one or more temperature sensors 109, a LAAC system 110, and a controller 112 (e.g., a BMC) implementing LAAC system control logic 114 and a LAAC control database 116. The LAAC system 110 is configured to cool the electronic equipment 108, and includes one or more LAAC pumps 111 coupled to a LAAC radiator (not shown). The controller 112 is configured to control operation of the LAAC system 110 utilizing the LAAC system control logic 114. The LAAC system control logic 114, for example, may obtain temperature information from the temperature sensors 109 associated with the electronic equipment 108 and utilize the temperature information to intelligently control the speed of operation of the LAAC pumps 111 of the LAAC system 110. This may be based on LAAC pump speed control policies which are stored in the LAAC control database 116. The LAAC system control logic 114 is further configured to monitor operation of the LAAC system 110 so as to detect failure or other interruption in operation of the LAAC pumps 111 of the LAAC system 110. On detecting such failure or other interruption, the LAAC system control logic 114 may adjust operation of the electronic equipment 108 accordingly to limit power consumption (and associated heat generation) thereof. This can advantageously prevent shutdown of the electronic equipment 108 and mitigate the risk of thermal damage to the electronic equipment 108.

Although not shown in FIG. 1 for clarity of illustration, one or more other ones of the IT assets 106-2 through 106-N may be configured in a manner similar to that described above with respect to the IT asset 106-1. Further, although FIG. 1 illustrates the LAAC system 110 being internal to the IT asset 106-1, this is not a requirement. In some cases, the LAAC system 110 may be used for an equipment rack or cabinet in which multiple IT assets, including the IT asset 106-1, are installed. Thus, the LAAC system 110 may be utilized for cooling of electronic equipment that is part of two or more physically distinct IT assets (e.g., two or more servers, storage systems, etc.). Still further, although FIG. 1 illustrates the temperature sensors 109 as being internal to the electronic equipment 108, this is not a requirement. The temperature sensors 109 may be at least partially external to the electronic equipment 108, may be mounted to the electronic equipment 108, etc.

In some embodiments, the IT asset 106-1 is used for an enterprise system. For example, an enterprise may have various IT assets, including the IT asset 106-1 and one or more other ones of the IT assets 106-2 through 106-N, which it operates in the IT infrastructure 105 (e.g., for running one or more software applications or other workloads of the enterprise) and which may be accessed by users of the enterprise system via the client devices 102. As used herein, the term “enterprise system” is intended to be construed broadly to include any group of systems or other computing devices. For example, the IT assets of the IT infrastructure 105 may provide a portion of one or more enterprise systems. A given enterprise system may also or alternatively include one or more of the client devices 102. In some embodiments, an enterprise system includes one or more data centers, cloud infrastructure comprising one or more clouds, etc. A given enterprise system, such as cloud infrastructure, may host assets that are associated with multiple enterprises (e.g., two or more different businesses, organizations or other entities).

The client devices 102 may comprise, for example, physical computing devices such as IoT devices, mobile telephones, laptop computers, tablet computers, desktop computers or other types of devices utilized by members of an enterprise, in any combination. Such devices are examples of what are more generally referred to herein as “processing devices.” Some of these processing devices are also generally referred to herein as “computers.” The client devices 102 may also or alternately comprise virtualized computing resources, such as VMs, containers, etc.

The client devices 102 in some embodiments comprise respective computers associated with a particular company, organization or other enterprise. Thus, the client devices 102 may be considered examples of assets of an enterprise system. In addition, at least portions of the information processing system 100 may also be referred to herein as collectively comprising one or more “enterprises.” Numerous other operating scenarios involving a wide variety of different types and arrangements of processing nodes are possible, as will be appreciated by those skilled in the art.

The network 104 is assumed to comprise a global computer network such as the Internet, although other types of networks can be part of the network 104, including a wide area network (WAN), a local area network (LAN), a satellite network, a telephone or cable network, a cellular network, a wireless network such as a WiFi or WiMAX network, or various portions or combinations of these and other types of networks.

Although not explicitly shown in FIG. 1, one or more input-output devices such as keyboards, displays or other types of input-output devices may be used to support one or more user interfaces to the IT assets 106, as well as to support communication between the IT assets 106 and other related systems and devices not explicitly shown.

In some embodiments, the client devices 102 are assumed to be associated with system administrators, IT managers or other authorized personnel responsible for managing the IT assets 106 of the IT infrastructure 105, including the IT asset 106-1. For example, a given one of the client devices 102 may be operated by a user to control or set policies for thermal management of the IT asset 106-1 which are persisted in the LAAC control database 116.

In some embodiments, the client devices 102 and the controller 112 or other components of the IT asset 106-1 may implement host agents that are configured for automated transmission of information regarding the IT asset 106-1 (e.g., health or other status information, alerts or other events, etc.). It should be noted that a “host agent” as this term is generally used herein may comprise an automated entity, such as a software entity running on a processing device. Accordingly, a host agent need not be a human entity.

The controller 112 in the FIG. 1 embodiment is assumed to be implemented using at least one processing device. Each such processing device generally comprises at least one processor and an associated memory, and implements one or more functional modules or logic for controlling certain features of the IT assets 106. In the FIG. 1 embodiment, the controller 112 implements the LAAC system control logic 114 as well as the LAAC control database 116. As discussed above, the LAAC system control logic 114 is configured to control operation of the electronic equipment 108 and the LAAC system 110 to achieve desired thermal characteristics. This includes, for example, the LAAC system control logic 114 throttling or limiting the power consumption of the electronic equipment 108 based on a monitored status of the LAAC system 110 (e.g., based on whether one or more of the LAAC pumps 111 has failed). This also includes, for example, the LAAC system control logic 114 controlling the LAAC system 110 (e.g., a speed of one or more of the LAAC pumps 111) based on a monitored status of the electronic equipment 108 (e.g., based on temperature information from the temperature sensors 109, reported workload or utilization of the electronic equipment 108, etc.). At least portions of the LAAC system control logic 114 may be implemented at least in part in the form of software that is stored in memory and executed by a processor.

The LAAC control database 116 is configured to store various information that is utilized by the LAAC system control logic 114. Such information may include, for example, health information for the electronic equipment 108, the LAAC system 110 (or components thereof such as the LAAC pumps 111), parameters or thresholds for controlling the electronic equipment 108 and/or the LAAC system 110 based on the health information, etc. The LAAC control database 116 may be implemented utilizing one or more storage systems. The term “storage system” as used herein is intended to be broadly construed. A given storage system, as the term is broadly used herein, can comprise, for example, content addressable storage, flash-based storage, network-attached storage (NAS), storage area networks (SANs), direct-attached storage (DAS) and distributed DAS, as well as combinations of these and other storage types, including software-defined storage. Other particular types of storage products that can be used in implementing storage systems in illustrative embodiments include all-flash and hybrid flash storage arrays, software-defined storage products, cloud storage products, object-based storage products, and scale-out NAS clusters. Combinations of multiple ones of these and other storage products can also be used in implementing a given storage system in an illustrative embodiment.

It is to be appreciated that the particular arrangement of the client devices 102, the IT infrastructure 105 and the IT assets 106 illustrated in the FIG. 1 embodiment is presented by way of example only, and alternative arrangements can be used in other embodiments. As discussed above, for example, the LAAC system 110 may in some embodiments be implemented external to the IT asset 106-1 rather than internal to the IT asset 106-1.

The IT assets 106 and other portions of the information processing system 100, as will be described in further detail below, may be part of cloud infrastructure.

The IT assets 106 and other components of the information processing system 100 in the FIG. 1 embodiment are assumed to be implemented using at least one processing platform comprising one or more processing devices each having a processor coupled to a memory. Such processing devices can illustratively include particular arrangements of compute, storage and network resources.

The client devices 102, IT infrastructure 105, the IT assets 106 or components thereof may be implemented on respective distinct processing platforms, although numerous other arrangements are possible. For example, in some embodiments at least portions of one or more of the IT assets 106 and one or more of the client devices 102 are implemented on the same processing platform. A given client device (e.g., 102-1) can therefore be implemented at least in part within at least one processing platform that implements at least a portion of one or more of the IT assets 106.

The term “processing platform” as used herein is intended to be broadly construed so as to encompass, by way of illustration and without limitation, multiple sets of processing devices and associated storage systems that are configured to communicate over one or more networks. For example, distributed implementations of the information processing system 100 are possible, in which certain components of the system reside in one data center in a first geographic location while other components of the system reside in one or more other data centers in one or more other geographic locations that are potentially remote from the first geographic location. Thus, it is possible in some implementations of the information processing system 100 for the client devices 102, the IT infrastructure 105, and the IT assets 106, or portions or components thereof, to reside in different data centers. Numerous other distributed implementations are possible.

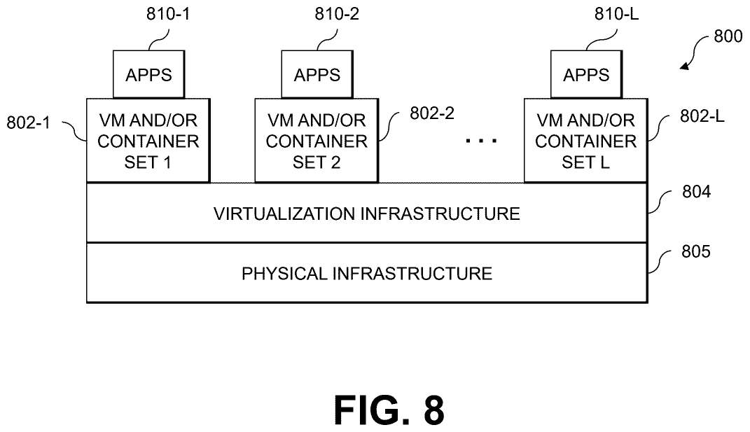

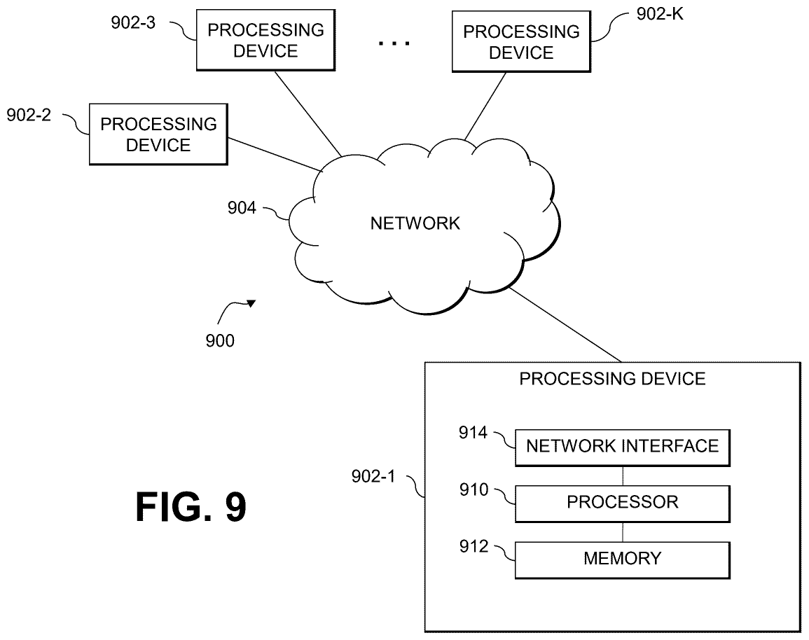

Additional examples of processing platforms utilized to implement the information processing system 100 in illustrative embodiments will be described in more detail below in conjunction with FIGS. 8 and 9.

It is to be appreciated that these and other features of illustrative embodiments are presented by way of example only, and should not be construed as limiting in any way.

It is to be understood that the particular set of elements shown in FIG. 1 for dynamic control of the LAAC system 110 is presented by way of illustrative example only, and in other embodiments additional or alternative elements may be used. Thus, another embodiment may include additional or alternative systems, devices and other network entities, as well as different arrangements of modules and other components.

It is to be appreciated that these and other features of illustrative embodiments are presented by way of example only, and should not be construed as limiting in any way.

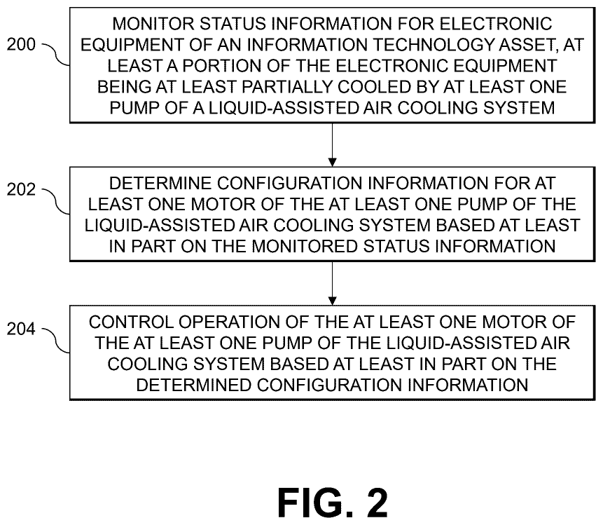

An exemplary process for dynamic control of a LAAC system will now be described in more detail with reference to the flow diagram of FIG. 2. It is to be understood that this particular process is only an example, and that additional or alternative processes for dynamic control of LAAC systems may be used in other embodiments.

In this embodiment, the process includes steps 200 through 204. These steps are assumed to be performed by the LAAC system control logic 114 of the controller 112 of the IT asset 106-1. The process begins with step 200, monitoring status information for electronic equipment (e.g., electronic equipment 108) of an IT asset (e.g., IT asset 106-1), at least a portion of the electronic equipment being at least partially cooled by at least one pump (e.g., one of LAAC pumps 111) of a LAAC system (e.g., LAAC system 110). The monitored status information may comprise temperature data from one or more temperature sensors (e.g., temperature sensors 109) associated with the electronic equipment, a utilization level of the electronic equipment, power consumption by the electronic equipment, combinations thereof, etc.

In step 202, configuration information for at least one motor of the at least one pump of the LAAC system is determined based at least in part on the monitored status information. In step 204, operation of the at least one motor of the at least one pump of the LAAC system is controlled based at least in part on the determined configuration information. The determined configuration information may comprise a target operating speed for the at least one motor of the at least one pump of the LAAC system, and controlling the operation of the at least one motor of the at least one pump of the LAAC system based at least in part on the determined configuration information may comprise setting a duty cycle of the at least one motor of the at least one pump to achieve the target operating speed.

In some embodiments, the steps 200, 202 and 204 of the FIG. 2 process are performed continuously or repeatedly over time (e.g., such that as the status information for the electronic equipment changes, the determined configuration information is updated in real-time and used to dynamically control the operation of the at least one motor of the at least one pump of the LAAC system).

In some embodiments, the electronic equipment comprises two or more hardware components, a first one of the two or more hardware components being at least partially cooled by a first pump of the LAAC system and a second one of the two or more hardware components being at least partially cooled by a second pump of the LAAC system. At least one of the first hardware component and the second hardware component may be a GPU. The monitored status information may comprise first status information for the first hardware component and second status information for the second hardware component, and determining the configuration information may comprise determining first configuration information for a first motor of the first pump of the LAAC system based at least in part on the first status information and determining second configuration information for a second motor of the second pump of the LAAC system based at least in part on the second status information, the first configuration information being different than the second configuration information.

The FIG. 2 process may further include monitoring for one or more failure conditions of the LAAC system and, responsive to detecting at least one of the one or more failure conditions of the LAAC system, adjusting operation of the electronic equipment. Adjusting operation of the electronic equipment may comprise limiting power consumption by at least a portion of the electronic equipment. At least one of the one or more failure conditions may comprise detecting a failure of the at least one pump of the LAAC system.

The particular processing operations and other system functionality described in conjunction with the flow diagram of FIG. 2 are presented by way of illustrative example only, and should not be construed as limiting the scope of the disclosure in any way. Alternative embodiments can use other types of processing operations. For example, as indicated above, the ordering of the process steps may be varied in other embodiments, or certain steps may be performed at least in part concurrently with one another rather than serially. Also, one or more of the process steps may be repeated periodically, or multiple instances of the process can be performed in parallel with one another in order to implement a plurality of different processes for different IT assets, for different LAAC systems, etc.

Functionality such as that described in conjunction with the flow diagram of FIG. 2 can be implemented at least in part in the form of one or more software programs stored in memory and executed by a processor of a processing device such as a computer or server. As will be described below, a memory or other storage device having executable program code of one or more software programs embodied therein is an example of what is more generally referred to herein as a “processor-readable storage medium.”

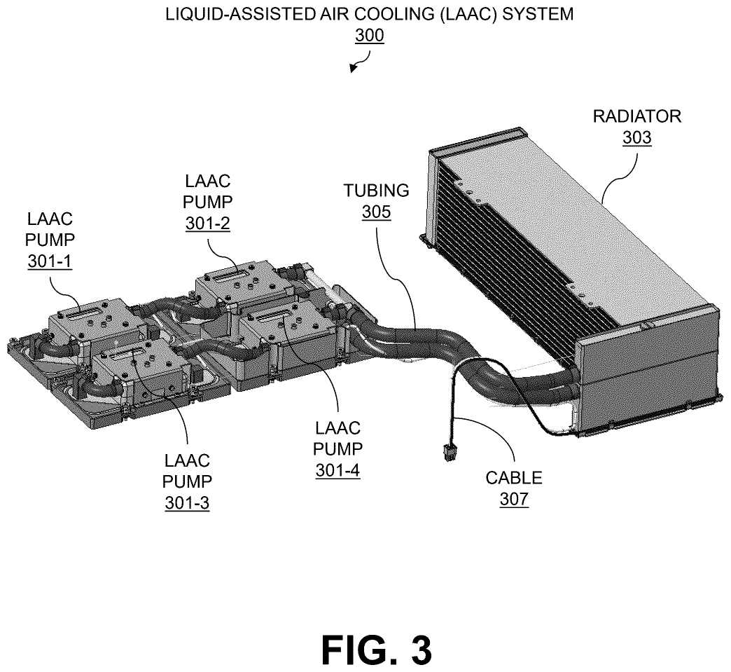

FIG. 3 shows an example implementation of a LAAC system 300, including a set of four LAAC pumps 301-1, 301-2, 301-3 and 301-4 (collectively, LAAC pumps 301) which are fluidly coupled to a radiator 303 (also referred to as a heat exchanger) via tubing 305. The LAAC pumps 301 are used to drive liquid to circulate inside a closed loop, where heat from one or more heat sources (e.g., electronic equipment such as one or more GPUs or other hardware accelerators installed in a server) is transferred to plates of the LAAC pumps 301, with the heat being absorbed by the liquid which flows through the tubing 305 and is dissipated to the air through the radiator 303. In the LAAC system 300, both liquid and air are involved which provides for effective heat transfer capability. The LAAC system 300 further includes a cable 307 for connecting the LAAC system 300 to a power source (e.g., directly or through a motherboard or other circuit board of a server, such as a PDB CPLD).

In conventional approaches, all the LAAC pumps 301 of the LAAC system 300 operate at 100% always by default. If each of the LAAC pumps 301 operates at 24 watts (W), then the LAAC system 300 consumes 96W of power all the time. In order to cool the radiator 303, fans (e.g., GPU fans) also typically run at a high RPM, which consumes additional power and contribute acoustic noise. Any liquid leak or pump failure in the LAAC system 300 is managed by a PDB CPLD (now shown in FIG. 3) to which the LAAC system 300 is connected via the cable 307. The PDB CPLD, on detecting pump failure or liquid leak, will assert a system shutdown event.

It should be noted that while FIG. 3 shows an example implementation of a LAAC system which utilizes four LAAC pumps, this is not a requirement. In other implementations, a LAAC system may utilize more or fewer than four LAAC pumps. Further, while in the example implementation of a LAAC system shown in FIG. 3 all of the LAAC pumps are connected to a single radiator or heat exchanger, in other embodiments, different ones or subsets of the LAAC pumps may be connect to different radiators or heat exchangers.

The technical solutions described herein provide functionality for more intelligent management of LAAC systems such as LAAC system 300, where a controller of a server or other IT asset to which a LAAC system is connected is used to control the LAAC system. The controller may comprise, for example, an integrated Dell Remote Access Controller (iDRAC) or BMC, which utilizes sideband management to control the LAAC system. The sideband management may utilize an Inter-Integrated Circuit (I2C) serial communication bus. The controller may be configured to operate in open and closed loop control modes. In the open loop control mode, the motors of the LAAC pumps of a LAAC system may be updated with a minimum baseline requirement for controlling liquid temperature. In the closed loop control mode, the LAAC pumps may be redundantly monitored (e.g., for failure) along with the electronic equipment being cooled to dynamically control the motor speed of the LAAC pumps. Further, if the controller detects failure of one or more of the LAAC pumps, the controller can initiate a power break signal (e.g., an GPU PWRBRK) so that the electronic equipment being cooled (e.g., GPUs) will be in use with limited power consumption without requiring a full system shutdown. In conventional approaches, the GPU PWRBRK is triggered only if there is a power supply failure.

In some embodiments, a combination of open loop and closed loop control modes are used for controlling pump speeds of the LAAC pumps of a LAAC system in a hybrid platform. The BMC or other controller is used to directly control the pump speeds of the LAAC pumps of the LAAC system, instead of relying on an indirect pump control mechanism. The open loop approach may be used during system initialization, when the system is idle, or in other system states (e.g., where communication with the BMC or other controller is interrupted). The closed loop approach may be used after system initialization, where the pump speeds of the LAAC pumps of the LAAC system are dynamically controlled (e.g., based on temperature readings from GPUs or other hardware accelerators or electronic equipment being cooled by the LAAC system which are obtained via a sideband interface). The technical solutions described herein further address potential issues such as system performance impacts or shutdown behavior caused by failure of LAAC pumps. The BMC or other controller is configured to implement power consumption reduction (e.g., through the GPU PWRBRK feature for GPUs) by limiting performance of the electronic equipment being controlled (e.g., within some defined threshold limits), thus mitigating the impact of LAAC pump failures on system performance and also protecting the electronic equipment from thermal damage. The technical solutions described herein are thus able to offer enhanced thermal management by directly controlling LAAC pump speeds through a BMC or other controller, utilizing open and closed loop control modes, and implementing a staged GPU PWRBRK or other power consumption reduction features to manage system performance and mitigate the consequences of LAAC pump failures.

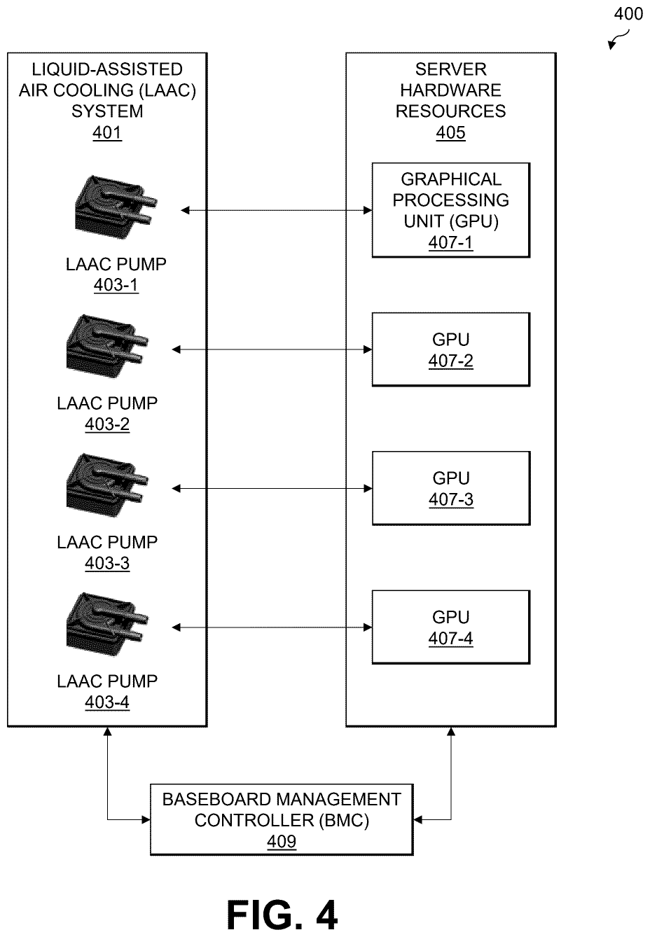

FIG. 4 shows a system 400 in which a LAAC system 401 with LAAC pumps 403-1, 403-2, 403-3 and 403-4 (collectively, LAAC pumps 403) is used for cooling of server hardware resources 405 including a set of GPUs 407-1, 407-2, 407-3 and 407-4 (collectively, GPUs 407). In this example, there is a one-to-one relationship between the LAAC pumps 403 and the GPUs 407 (e.g., where the plates of the different LAAC pumps 403 are assumed to be in contact with or close proximity to different ones of the GPUs 407 to absorb heat therefrom). This, however, is not a requirement. In other embodiments, a single LAAC pump may be configured to cool two or more GPUs or other types of electronic equipment. Further, it should be appreciated that LAAC systems may be used to cool various different types of server hardware resources or other electronic equipment, not just GPUs or other hardware accelerators. In the system 400, both the LAAC system 401 and the server hardware resources 405 are coupled with a BMC 409.

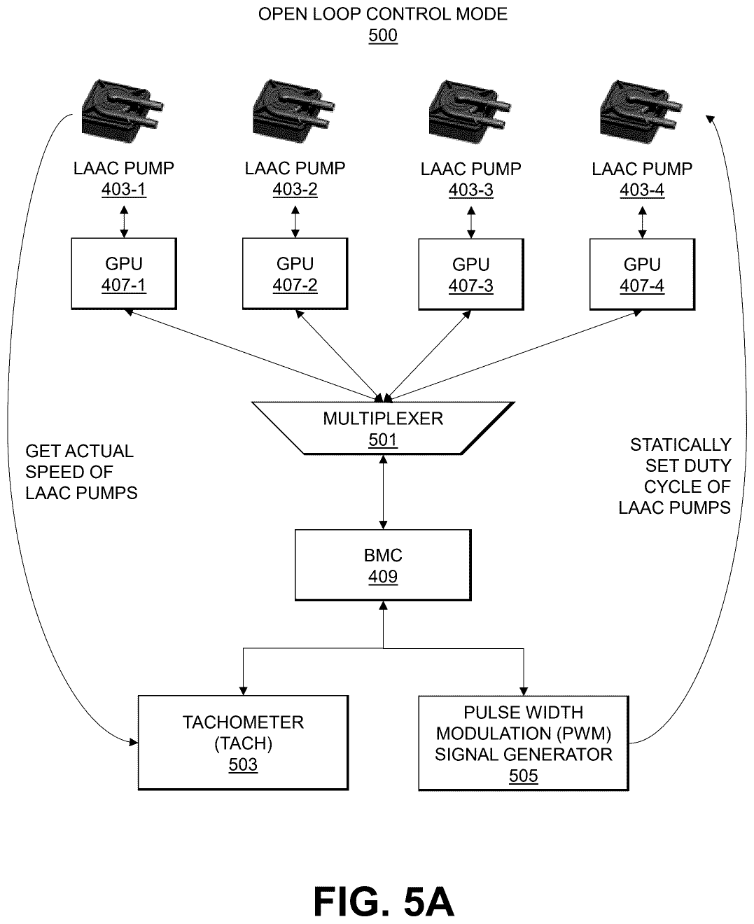

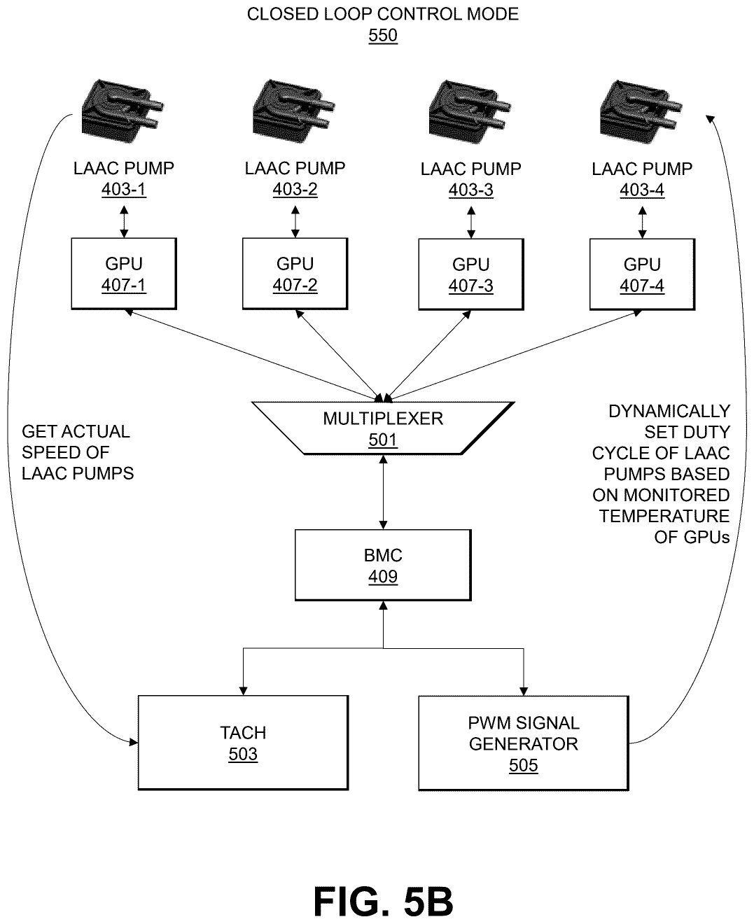

FIG. 5A shows an open loop control mode 500 for the system 400, and FIG. 5B shows a closed loop control mode 550 for the system 400. In both the open loop control mode 500 and the closed loop control mode 550, the BMC 409 is assumed to be coupled with the GPUs 407 via a multiplexer 501 (e.g., a sideband interface), and is coupled to a tachometer (TACH) 503 and a pulse width modulation (PWM) signal generator 505 associated with the LAAC system 401. The BMC 409 is configured to receive status information from the GPUs 407 via the multiplexer 501, where the status information may include, for example, temperature data from one or more temperature sensors which are integrated in or placed proximate to the GPUs 407, power consumption data for the GPUs 407, utilization or workload data for the GPUs 407, etc. The BMC 409 is also configured to receive status information from the LAAC pumps 403 via the TACH 503 (e.g., which measures the actual speed of the motors of the LAAC pumps 403). The BMC 409 is further configured to set the duty cycle (e.g., which controls the speed of the motors of the LAAC pumps 403) via the PWM signal generator 505. The BMC 409 is configured to set a default value for the duty cycle of the LAAC pumps 403 (e.g., in a PDB CPLD), which is used during system initialization or when the BMC 409 is unable to communicate with the LAAC pumps 403 in the open loop control mode 500. The BMC 409 is configured to dynamically set the duty cycle of the LAAC pumps 403 in the closed loop control mode 550 (e.g., based on the status information received from the GPUs 407 via the multiplexer 501 and the status information from the LAAC pumps 403 received via the TACH 503).

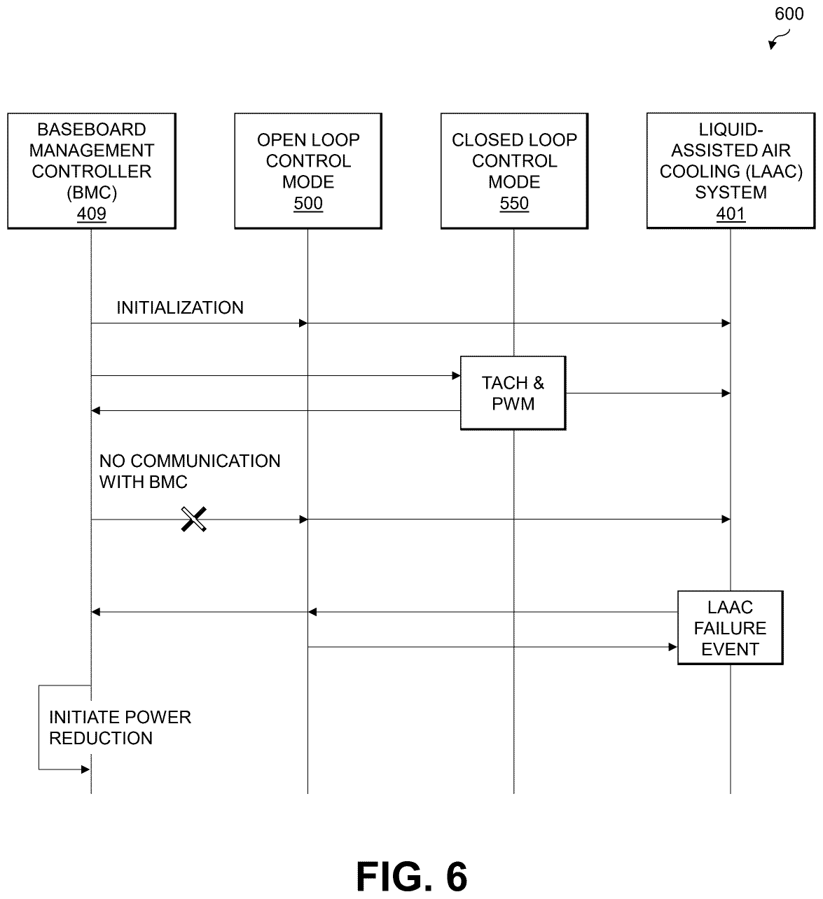

FIG. 6 shows a system flow 600 performed by the BMC 409 to control the LAAC system 401 in the open loop control mode 500 and the closed loop control mode 550. During system initialization, the BMC 409 triggers the open loop control mode 500. The open loop control mode 500 may also be triggered in scenarios where there is no communication with the BMC 409, in response to failure events, etc. The open loop control mode 500 takes control of the LAAC system 401 (e.g., the speed of the LAAC pumps 403) to manage the thermal conditions of the system 400 (e.g., using a statically set duty cycle). The closed loop control mode 550 becomes active once the system is operational (e.g., when the BMC 409 is able to communicate with the TACH 503 and the PWM signal generator 505). The closed loop control mode 550 continuously monitors the status of the electronic equipment being cooled (e.g., the GPUs 407 in the system 400, though as discussed above other types of electronic equipment may be cooled via the LAAC system 401 including central processing units (CPUs), network interface cards (NICs), etc.) and adjusts the pump speeds of the LAAC pumps 403 of the LAAC system 401 accordingly to maintain an optimal or desired set of thermal conditions. This may include setting different ones of the LAAC pumps 403 of the LAAC system 401 to different speeds (e.g., based on differing status information for the GPUs or other electronic equipment being cooled by different ones of the LAAC pumps 403). In the case of failure conditions (e.g., failure of the LAAC system 401 or one or more components thereof such as one or more of the LAAC pumps 403, a liquid leak, etc.), the BMC 409 is configured to intervene (e.g., by setting the staged GPU PWRBRK) to limit the power consumption of the GPUs 407 (or other electronic equipment being cooled by the LAAC system 401) to prevent overheating or system instability caused by reduced cooling due to the detected failure conditions.

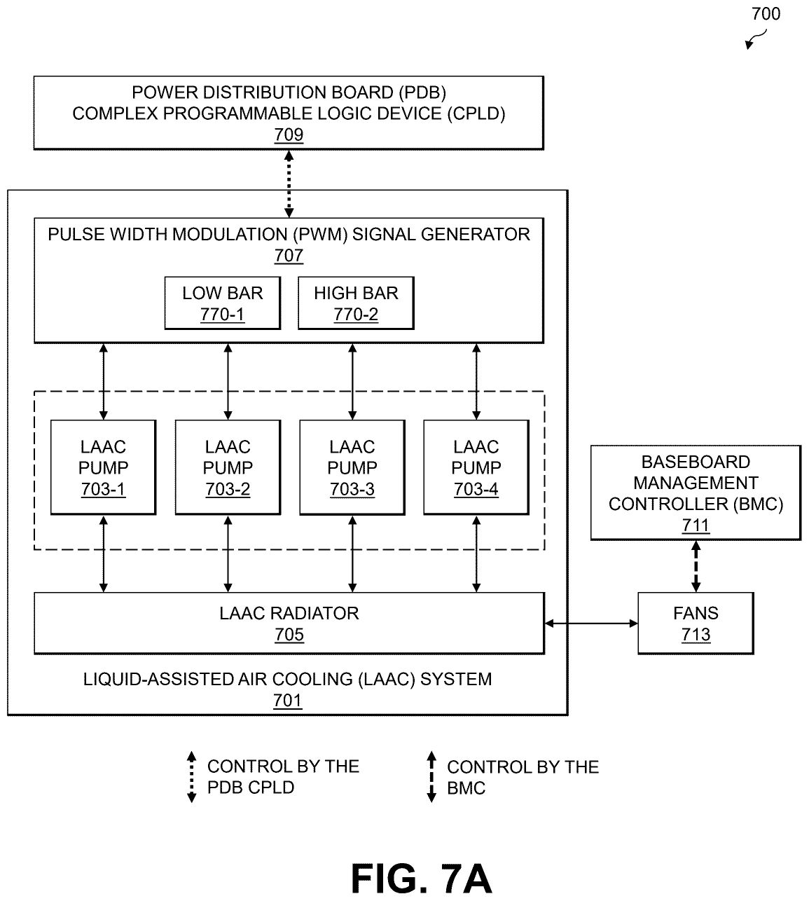

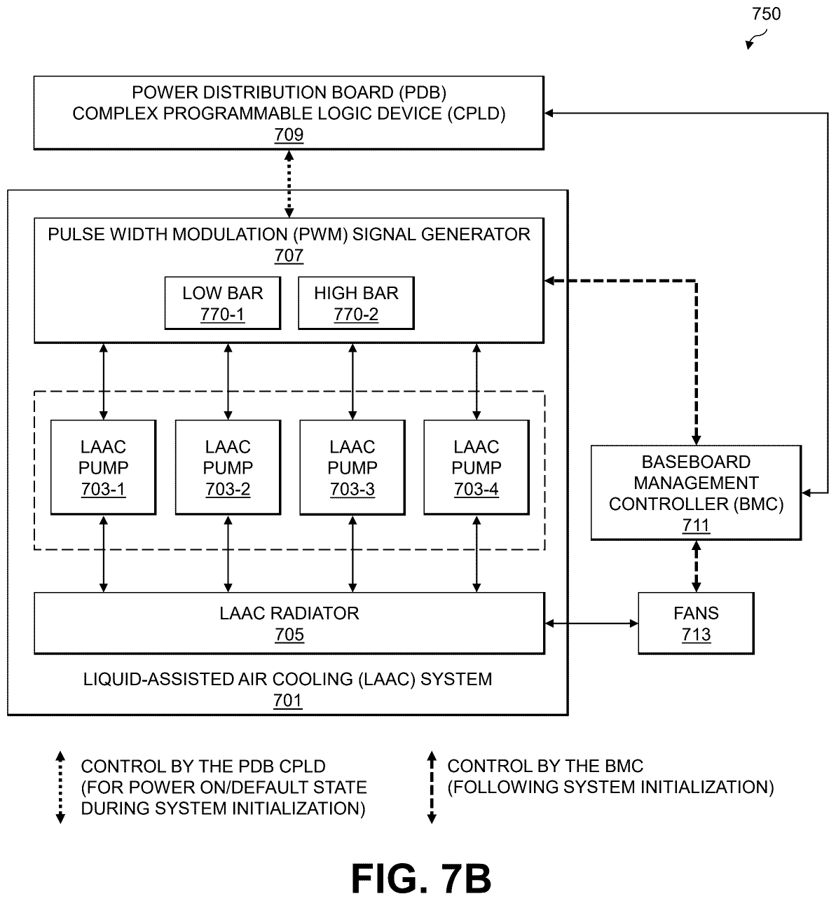

FIGS. 7A and 7B show respective implementations 700 and 750 for control of a LAAC system 701. The LAAC system 701 includes a set of LAAC pumps 703-1, 703-2, 703-3 and 703-4 (collectively, LAAC pumps 703) which are coupled to a LAAC radiator 705. The LAAC system 701 further includes a PWM signal generator 707, which is associated with a low bar 770-1 (e.g., a lower limit) and a high bar 770-2 (e.g., an upper limit). In addition, there is a PDB CPLD 709 which is coupled to the PWM signal generator 707, and a BMC 711 which is coupled to a set of one or more fans 713 which are used to facilitate heat dissipation by the LAAC radiator 705. In the implementation 700, the PDB CPLD 709 controls the PWM signal generator 707 to statically set the duty cycle for the LAAC pumps 703 while the BMC 711 controls the fans 713. In the implementation 750, the PDB CPLD 709 only controls the PWM signal generator 707 to statically set the duty cycle (e.g., specified by the BMC 711) for the LAAC pumps 703 during system initialization (e.g., a power on or default state). Following system initialization (e.g., when the BMC 711 is in communication with the PWM signal generator 707), the BMC 711 controls the PWM signal generator 707 to dynamically control the duty cycle of the LAAC pumps 703 based on status information from the electronic equipment being cooled by the LAAC pumps 703. The BMC 711 also controls the fans 713.

It is to be appreciated that the particular advantages described above and elsewhere herein are associated with particular illustrative embodiments and need not be present in other embodiments. Also, the particular types of information processing system features and functionality as illustrated in the drawings and described above are exemplary only, and numerous other arrangements may be used in other embodiments.

Illustrative embodiments of processing platforms utilized to implement functionality for dynamic control of LAAC systems will now be described in greater detail with reference to FIGS. 8 and 9. Although described in the context of system 100, these platforms may also be used to implement at least portions of other information processing systems in other embodiments.

FIG. 8 shows an example processing platform comprising cloud infrastructure 800. The cloud infrastructure 800 comprises a combination of physical and virtual processing resources that may be utilized to implement at least a portion of the information processing system 100 in FIG. 1. The cloud infrastructure 800 comprises multiple virtual machines (VMs) and/or container sets 802-1, 802-2, . . . 802-L implemented using virtualization infrastructure 804. The virtualization infrastructure 804 runs on physical infrastructure 805, and illustratively comprises one or more hypervisors and/or operating system level virtualization infrastructure. The operating system level virtualization infrastructure illustratively comprises kernel control groups of a Linux operating system or other type of operating system.

The cloud infrastructure 800 further comprises sets of applications 810-1, 810-2, . . . 810-L running on respective ones of the VMs/container sets 802-1, 802-2, . . . 802-L under the control of the virtualization infrastructure 804. The VMs/container sets 802 may comprise respective VMs, respective sets of one or more containers, or respective sets of one or more containers running in VMs.

In some implementations of the FIG. 8 embodiment, the VMs/container sets 802 comprise respective VMs implemented using virtualization infrastructure 804 that comprises at least one hypervisor. A hypervisor platform may be used to implement a hypervisor within the virtualization infrastructure 804, where the hypervisor platform has an associated virtual infrastructure management system. The underlying physical machines may comprise one or more distributed processing platforms that include one or more storage systems.

In other implementations of the FIG. 8 embodiment, the VMs/container sets 802 comprise respective containers implemented using virtualization infrastructure 804 that provides operating system level virtualization functionality, such as support for Docker containers running on bare metal hosts, or Docker containers running on VMs. The containers are illustratively implemented using respective kernel control groups of the operating system.

As is apparent from the above, one or more of the processing modules or other components of system 100 may each run on a computer, server, storage device or other processing platform element. A given such element may be viewed as an example of what is more generally referred to herein as a “processing device.” The cloud infrastructure 800 shown in FIG. 8 may represent at least a portion of one processing platform. Another example of such a processing platform is processing platform 900 shown in FIG. 9.

The processing platform 900 in this embodiment comprises a portion of system 100 and includes a plurality of processing devices, denoted 902-1, 902-2, 902-3, . . . 902-K, which communicate with one another over a network 904.

The network 904 may comprise any type of network, including by way of example a global computer network such as the Internet, a WAN, a LAN, a satellite network, a telephone or cable network, a cellular network, a wireless network such as a WiFi or WiMAX network, or various portions or combinations of these and other types of networks.

The processing device 902-1 in the processing platform 900 comprises a processor 910 coupled to a memory 912.

The processor 910 may comprise a microprocessor, a microcontroller, an application-specific integrated circuit (ASIC), a field-programmable gate array (FPGA), a central processing unit (CPU), a graphical processing unit (GPU), a tensor processing unit (TPU), a video processing unit (VPU) or other type of processing circuitry, as well as portions or combinations of such circuitry elements.

The memory 912 may comprise random access memory (RAM), read-only memory (ROM), flash memory or other types of memory, in any combination. The memory 912 and other memories disclosed herein should be viewed as illustrative examples of what are more generally referred to as “processor-readable storage media” storing executable program code of one or more software programs.

Articles of manufacture comprising such processor-readable storage media are considered illustrative embodiments. A given such article of manufacture may comprise, for example, a storage array, a storage disk or an integrated circuit containing RAM, ROM, flash memory or other electronic memory, or any of a wide variety of other types of computer program products. The term “article of manufacture” as used herein should be understood to exclude transitory, propagating signals. Numerous other types of computer program products comprising processor-readable storage media can be used.

Also included in the processing device 902-1 is network interface circuitry 914, which is used to interface the processing device with the network 904 and other system components, and may comprise conventional transceivers.

The other processing devices 902 of the processing platform 900 are assumed to be configured in a manner similar to that shown for processing device 902-1 in the figure.

Again, the particular processing platform 900 shown in the figure is presented by way of example only, and system 100 may include additional or alternative processing platforms, as well as numerous distinct processing platforms in any combination, with each such platform comprising one or more computers, servers, storage devices or other processing devices.

For example, other processing platforms used to implement illustrative embodiments can comprise converged infrastructure.

It should therefore be understood that in other embodiments different arrangements of additional or alternative elements may be used. At least a subset of these elements may be collectively implemented on a common processing platform, or each such element may be implemented on a separate processing platform.

As indicated previously, components of an information processing system as disclosed herein can be implemented at least in part in the form of one or more software programs stored in memory and executed by a processor of a processing device. For example, at least portions of the functionality for dynamic control of LAAC systems as disclosed herein are illustratively implemented in the form of software running on one or more processing devices.

It should again be emphasized that the above-described embodiments are presented for purposes of illustration only. Many variations and other alternative embodiments may be used. For example, the disclosed techniques are applicable to a wide variety of other types of information processing systems, IT assets, chassis configurations, etc. Also, the particular configurations of system and device elements and associated processing operations illustratively shown in the drawings can be varied in other embodiments. Moreover, the various assumptions made above in the course of describing the illustrative embodiments should also be viewed as exemplary rather than as requirements or limitations of the disclosure. Numerous other alternative embodiments within the scope of the appended claims will be readily apparent to those skilled in the art.

What is claimed is:

1. An apparatus comprising:
at least one processing device comprising a processor coupled to a memory;
the at least one processing device being configured:
to monitor status information for electronic equipment of an information technology asset, at least a portion of the electronic equipment being at least partially cooled by at least one pump of a liquid-assisted air cooling system;
to determine configuration information for at least one motor of the at least one pump of the liquid-assisted air cooling system based at least in part on the monitored status information; and
to control operation of the at least one motor of the at least one pump of the liquid-assisted air cooling system based at least in part on the determined configuration information.

2. The apparatus of claim 1 wherein the at least one processing device comprises a baseboard management controller of the information technology asset.

3. The apparatus of claim 2 wherein the baseboard management controller is coupled with the liquid-assisted air cooling system utilizing a serial communication bus.

4. The apparatus of claim 1 wherein the monitored status information comprises temperature data from one or more temperature sensors associated with the electronic equipment.

5. The apparatus of claim 1 wherein the monitored status information comprises at least one of:
a utilization level of the electronic equipment; and
power consumption by the electronic equipment.

6. The apparatus of claim 1 wherein the electronic equipment comprises two or more hardware components, a first one of the two or more hardware components being at least partially cooled by a first pump of the liquid-assisted air cooling system and a second one of the two or more hardware components being at least partially cooled by a second pump of the liquid-assisted air cooling system.

7. The apparatus of claim 6 wherein at least one of the first hardware component and the second hardware component comprises a graphical processing unit.

8. The apparatus of claim 6 wherein the monitored status information comprises first status information for the first hardware component and second status information for the second hardware component, and wherein determining the configuration information comprises determining first configuration information for a first motor of the first pump of the liquid-assisted air cooling system based at least in part on the first status information and determining second configuration information for a second motor of the second pump of the liquid-assisted air cooling system based at least in part on the second status information, the first configuration information being different than the second configuration information.

9. The apparatus of claim 1 wherein the determined configuration information comprises a target operating speed for the at least one motor of the at least one pump of the liquid-assisted air cooling system.

10. The apparatus of claim 9 wherein controlling the operation of the at least one motor of the at least one pump of the liquid-assisted air cooling system based at least in part on the determined configuration information comprises setting a duty cycle of the at least one motor of the at least one pump to achieve the target operating speed.

11. The apparatus of claim 1 wherein the at least one processing device is further configured to monitor for one or more failure conditions of the liquid-assisted air cooling system.

12. The apparatus of claim 11 wherein the at least one processing device is further configured, responsive to detecting at least one of the one or more failure conditions of the liquid-assisted air cooling system, to adjust operation of the electronic equipment.

13. The apparatus of claim 12 wherein adjusting operation of the electronic equipment comprises limiting power consumption by at least a portion of the electronic equipment.

14. The apparatus of claim 11 wherein at least one of the one or more failure conditions comprises detecting a failure of the at least one pump of the liquid-assisted air cooling system.

15. A computer program product comprising a non-transitory processor-readable storage medium having stored therein program code of one or more software programs, wherein the program code when executed by at least one processing device causes the at least one processing device:
to monitor status information for electronic equipment of an information technology asset, at least a portion of the electronic equipment being at least partially cooled by at least one pump of a liquid-assisted air cooling system;
to determine configuration information for at least one motor of the at least one pump of the liquid-assisted air cooling system based at least in part on the monitored status information; and
to control operation of the at least one motor of the at least one pump of the liquid-assisted air cooling system based at least in part on the determined configuration information.

16. The computer program product of claim 15 wherein the determined configuration information comprises a target operating speed for the at least one motor of the at least one pump of the liquid-assisted air cooling system, and wherein controlling the operation of the at least one motor of the at least one pump of the liquid-assisted air cooling system based at least in part on the determined configuration information comprises setting a duty cycle of the at least one motor of the at least one pump to achieve the target operating speed.

17. The computer program product of claim 15 wherein the program code when executed by the at least one processing device further causes the at least one processing device:
to monitor for one or more failure conditions of the liquid-assisted air cooling system; and
responsive to detecting at least one of the one or more failure conditions of the liquid-assisted air cooling system, to adjust operation of the electronic equipment.

18. A method comprising:
monitoring status information for electronic equipment of an information technology asset, at least a portion of the electronic equipment being at least partially cooled by at least one pump of a liquid-assisted air cooling system;
determining configuration information for at least one motor of the at least one pump of the liquid-assisted air cooling system based at least in part on the monitored status information; and
controlling operation of the at least one motor of the at least one pump of the liquid-assisted air cooling system based at least in part on the determined configuration information;
wherein the method is performed by at least one processing device comprising a processor coupled to a memory.

19. The method of claim 18 wherein the determined configuration information comprises a target operating speed for the at least one motor of the at least one pump of the liquid-assisted air cooling system, and wherein controlling the operation of the at least one motor of the at least one pump of the liquid-assisted air cooling system based at least in part on the determined configuration information comprises setting a duty cycle of the at least one motor of the at least one pump to achieve the target operating speed.

20. The method of claim 18 further comprising:
monitoring for one or more failure conditions of the liquid-assisted air cooling system; and
responsive to detecting at least one of the one or more failure conditions of the liquid-assisted air cooling system, adjusting operation of the electronic equipment.
